(19) United States
(12) Patent Application Publication
(10) Pub. No.: US 2025/0382701 A1
(43) Pub. Date: Dec. 18, 2025

(54) SYSTEMS FOR ON-SITE PURIFICATION AND RELATED METHODS

(71) Applicant: ENTEGRIS, INC., Billerica, MA (US)

(72) Inventors: Lucas B. Henderson, Danbury, CT (US); Bryan C. Hendrix, Danbury, CT (US); Scott L. Battle, Cedar Park, TX (US); Michael Watson, Leander, TX (US)

(21) Appl. No.: 19/237,977

(22) Filed: Jun. 13, 2025

Related U.S. Application Data
(60) Provisional application No. 63/660,351, filed on Jun. 14, 2024.

(51) Int. Cl. C23C 16/44; C23C 16/448; C23C 16/455; C23C 16/52

(52) U.S. Cl. CPC C23C 16/4402; C23C 16/4485; C23C 16/45561; C23C 16/52

(57) ABSTRACT

Some embodiments relate to systems and related methods. A system comprises a cabinet. The cabinet comprises a first ampoule. The first ampoule comprises a first precursor material and at least one first impurity. The cabinet comprises a manifold. The manifold is connectable to a tool. The cabinet comprises a first valve. The first valve connects the first ampoule to the manifold. The first valve has not been exposed to an external environment after the first valve has been exposed to the first precursor material.

### CROSS-REFERENCE TO RELATED APPLICATIONS

This application claims the benefit under 35 USC 119 of U.S. Provisional Patent Application No. 63/660,351, filed Jun. 14, 2024, the disclosure of which is hereby incorporated herein by reference in its entirety.

### FIELD

The present disclosure relates to systems for on-site purification and related methods.

### BACKGROUND

Vapor deposition processes can involve delivering precursors to tools.

### SUMMARY

Some embodiments relate to a system. In some embodiments, the system comprises a cabinet. In some embodiments, the cabinet comprises a first ampoule. In some embodiments, the first ampoule comprises a first precursor material and at least one first impurity. In some embodiments, the cabinet comprises a manifold. In some embodiments, the manifold is connectable to a tool. In some embodiments, the cabinet comprises a first valve. In some embodiments, the first valve connects the first ampoule to the manifold. In some embodiments, the first valve has not been exposed to an external environment after the first valve has exposed to the first precursor material.

Some embodiments relate to a method. In some embodiments, the method comprises the steps of obtaining a cabinet; and removing at least a portion of the at least one first impurity from the first ampoule. In some embodiments, the cabinet comprises a first ampoule. In some embodiments, the first ampoule comprises a first precursor material and at least one first impurity. In some embodiments, the cabinet comprises a manifold connectable to a tool. In some embodiments, the cabinet comprises a first valve. In some embodiments, the first valve connects the first ampoule to the manifold. In some embodiments, prior to the step of removing, the first valve has not been exposed to an external environment after the first valve has exposed to the first precursor material.

Some embodiments relate to a system. In some embodiments, the system comprises a cabinet. In some embodiments, the cabinet comprises a first ampoule. In some embodiments, the first ampoule comprises a first precursor material and at least one first impurity. In some embodiments, the cabinet comprises a manifold. In some embodiments, the manifold is connectable to a semiconductor tool. In some embodiments, the cabinet comprises a first heater. In some embodiments, the first heater is configured to heat the first ampoule. In some embodiments, the cabinet comprises a first valve. In some embodiments, the first valve connects the first ampoule to the manifold. In some embodiments, the first valve has not been exposed to an external environment after the first valve has been exposed to the first precursor material.

### DRAWINGS

FIG. 1 is a schematic diagram of a system, according to some embodiments.

FIG. 2 is a schematic diagram of a system, according to some embodiments.

FIG. 3 is a flowchart of a method, according to some embodiments.

FIG. 4 is schematic diagram of a system, according to some embodiments.

FIG. 5 is a schematic diagram of a system, according to some embodiments.

FIGS. 6A and 6B are a schematic diagrams of systems, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

Delivery of precursor material to a tool without precursor particles, precursor vapor and other corrosive vapors may be achieved on-site at a user facility. The cabinets may be fabricated to contain processing equipment needed for on-site purification of the ampoules prior to use. Some embodiments provided herein overcome at least these challenges by providing systems and related methods for on-site purification. The systems and methods provided herein reduce precursor particles, precursor vapor and other corrosive vapors in an ampoule prior to delivery to a tool. In addition, in some embodiments, the systems and methods may be completed simultaneously with an ampoule in-service.

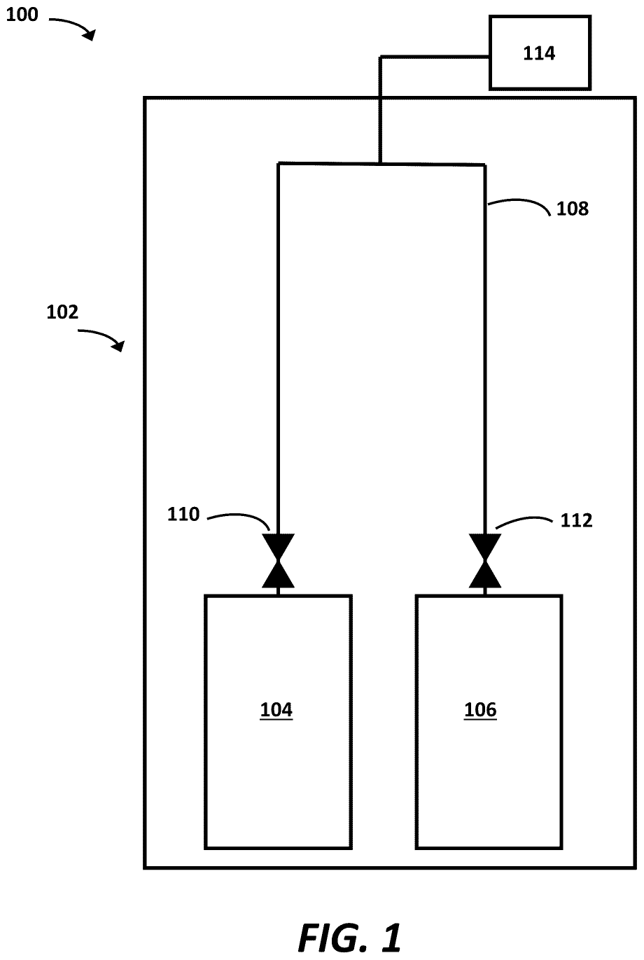

FIG. 1 is a schematic diagram of a system, according to some embodiments. In some embodiments, the system 100 comprises a cabinet 102. In some embodiments, the system 100 is located at a customer site. As shown in FIG. 1, the cabinet 102 houses a first ampoule 104. The first ampoule 104 comprises a first precursor material and at least one first impurity.

The cabinet 102 houses a second ampoule 106. The second ampoule 106 comprises a second precursor material. In some embodiments, the second ampoule 106 comprises at least one second impurity.

In some embodiments, the first ampoule 104 and the second ampoule 106 are at ambient temperature.

The first ampoule and the second ampoule may comprise a molybdenum precursor having sufficiently low levels of impurities. The impurities may include, for example and without limitation, at least one of a molybdenum precursor, a molybdenum impurity, a non-molybdenum impurity, or any combination thereof. In some embodiments, the molybdenum precursor comprises molybdenum pentachloride (MoCl₅). In some embodiments, the molybdenum precursor comprises molybdenum dioxydichloride (MoO₂Cl₂) In some embodiments, the molybdenum impurity comprises at least one of a molybdenum oxychloride, a molybdenum chloride (other than MoCl₅), a molybdenum oxide, or any combination thereof. In some embodiments, the molybdenum impurity comprises at least one of molybdenum tetrachloride (MoCl₄), molybdenum oxytetrachloride (MoOCl₄), molybdenum dioxydichloride hydrate (MoO₂Cl₂ (H₂O)), molybdenum trioxide (MoO₃), or any combination thereof. In some embodiments, the molybdenum impurity comprises a non-volatile molybdenum impurity. In some embodiments, the non-volatile molybdenum impurity comprises at least one of molybdenum tetrachloride (MoCl₄), molybdenum trioxide (MoO₃), or any combination thereof. In some embodiments, the molybdenum impurity comprises a volatile molybdenum impurity. In some embodiments, the volatile molybdenum impurity comprises at least one of molybdenum oxytetrachloride (MoOCl₄), molybdenum dioxydichloride hydrate (MoO₂Cl₂ (H₂O)), or any combination thereof. In some embodiments, the non-molybdenum impurity comprises a compound or molecule which does not comprise molybdenum. In some embodiments, the non-molybdenum impurity comprises at least one of HCl, hydrocarbons, metal-containing molecules, water or any combination thereof.

In some embodiments, a MoCl₅ precursor material has a low molybdenum impurity content. In some embodiments, the MoCl₅ precursor material comprises 0.01% to 2% by weight of the molybdenum impurity based on a total weight of the MoCl₅ precursor material, or any range or subrange between 0.01% to 2%. In some embodiments, the MoCl₅ precursor material comprises 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, or 0.01% to 0.05% by weight of the molybdenum impurity based on the total weight of the MoCl₅ precursor material. In some embodiments, the MoCl₅ precursor material comprises 0.05% to 1%, 0.1% to 1%, 0.2% to 1%, 0.3% to 1%, 0.4% to 1%, 0.5% to 1%, 0.6% to 1%, 0.7% to 1%, 0.8% to 1%, or 0.9% to 1% by weight of the molybdenum impurity based on the total weight of the MoCl₅ precursor material.

In some embodiments, a MoO₂Cl₂ precursor material has a low molybdenum impurity content. In some embodiments, the MoO₂Cl₂ precursor material comprises 0.01% to 2% by weight of the molybdenum impurity based on a total weight of the MOO₂Cl₂ precursor material, or any range or subrange between 0.01% to 2%. In some embodiments, the MoCl₅ precursor comprises 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, or 0.01% to 0.05% by weight of the molybdenum impurity based on the total weight of the MoO₂Cl₂ precursor material. In some embodiments, the MoO₂Cl₂ precursor material comprises 0.05% to 1%, 0.1% to 1%, 0.2% to 1%, 0.3% to 1%, 0.4% to 1%, 0.5% to 1%, 0.6% to 1%, 0.7% to 1%, 0.8% to 1%, or 0.9% to 1% by weight of the molybdenum impurity based on the total weight of the MoO₂Cl₂ precursor material.

In some embodiments, a MoOCl₄ precursor material has a low molybdenum impurity content. Exemplary impurities in MoOCl₄ include hydrates of MoOCl₄ and MoCl₅. In some embodiments, the MoOCl₄ precursor material comprises 0.01% to 2% by weight of the molybdenum impurity based on a total weight of the MoOCl₄ precursor material, or any range or subrange between 0.01% to 2%. In some embodiments, the MoOCl₄ hydrate precursor comprises 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, or 0.01% to 0.05% by weight of the molybdenum impurity based on the total weight of the MoOCl₄ precursor material. In some embodiments, the MoOCl₄ precursor material comprises 0.05% to 1%, 0.1% to 1%, 0.2% to 1%, 0.3% to 1%, 0.4% to 1%, 0.5% to 1%, 0.6% to 1%, 0.7% to 1%, 0.8% to 1%, or 0.9% to 1% by weight of the molybdenum impurity based on the total weight of the MoOCl₄ precursor material.

The precursor vessel may comprise a tungsten precursor material, such as for example and without limitation, a tungsten pentachloride (WCl₅) precursor material, having sufficiently low levels of impurities. The impurities may include, for example and without limitation, at least one impurity of WOCl₄, WCl₄ or any combination thereof.

In some embodiments, the at least one impurity comprises a carbon material. In some embodiments, the carbon-containing material comprises at least one of a volatile compound (e.g., a volatile carbon-containing material), a non-volatile compound (e.g., a non-volatile carbon-containing material), or any combination thereof. In some embodiments, the at least one impurity comprises a chlorinated hydrocarbon. In some embodiments, the carbon-containing material comprises at least one of hydrocarbon polymers, haloalkanes, haloalkenes, halocycloalkanes, halo-substituted arenes, or any combination thereof. In some embodiments, the carbon-containing material comprises a substituent (e.g., a functional group(s)). In some embodiments, the carbon-containing material comprises a volatile carbon species that is volatile at conditions of vaporizing the tungsten precursor. In some embodiments, the carbon-containing material comprises entrained particular carbon species (e.g., species to be captured by a filter). In some embodiments, the at least one impurity comprises at least one of dichloromethane, phosgene, 1,1-dichloroethane, chloroform, 1,2-dichloroethane, carbon tetrachloride, tetrachloroethylene, trichlorethylene, 1,3-, dichloropropane, 1,2,3-trichloropropane, 1,2-dichloropropane, 1,1,2-trichloroethane, 1,1,2-trichloropropane, 1,2,2-trichloropropane, 1,1,2,3-tetrachloropropane, 1,2,2,3-tetrachloropropane, 1,1,2,2,-tetrachloroethane, 2,2-dichloropropanoyl chloride, 1,3-dichloro-1-propene, 3,3,3-trichloro-1-propene, 1,2,3-trichloro-1-propene, 1,3-dichloro-2-methylenepropane, 1,4-dichlorobutane, 1,3-dichloro-2-butene, 1,1,3,3-tetrachloro-2-methylpropane, 1,1,2,3,3-pentachloropropane, 1,3-dichlorocyclopentane, 1,1,2,2,3,3-hexachloropropane, 1,2,3,4,5,5-hexanechloro-1,3-cyclopentadiene, trichlorocyclopentene, tetrachlorocyclopentene, pentachloronorbornene or any combination thereof.

The precursor may comprise less than 0.05% by weight of the carbon material based on a total weight of the WCl₅ precursor material, or any range or subrange therebetween. In some embodiments, the WCl₅ precursor material comprises less than 0.02%, less than 0.019%, less than 0018%, less than 0017%, less than 0016%, less than 0.015%, less than 0.014%, less than 0.013%, less than 0.012%, less than 0.011%, less than 0.010%, less than 0.009%, less than 0.008%, less than 0.007%, less than 0.006%, less than 0.005%, less than 0.004%, less than 0.003%, less than 0.002%, less than 0.001%, less than 0.0009%, less than 0.0008%, less than 0.0007%, less than 0.0006%, less than 0.0005%, less than 0.0004%, less than 0.0003%, less than 0.0002%, or less than 0.0001% by weight of the carbon material based on the total weight of the precursor as measured by Total Carbon analysis using Non-Dispersive Infrared Detection.

The precursor may comprise 0.0001% to 0.05% by weight of the carbon material based on the total weight of the WCl₅ precursor material, or any range or subrange therebetween. In some embodiments, the WCl₅ precursor material comprises 0.0001% to 0.02%, 0.0001% to 0.019%, 0.0001% to 0.018%, 0.0001% to 0.017%, 0.0001% to 0.016%, 0.0001% to 0.015%, 0.0001% to 0.014%, 0.0001% to 0.013%, 0.0001% to 0.012%, 0.0001% to 0.011%, 0.0001% to 0.010%, 0.0001% to 0.009%, 0.0001% to 0.008%, 0.0001% to 0.007%, 0.0001% to 0.006%, 0.0001% to 0.005%, 0.0001% to 0.004%, 0.0001% to 0.003%, 0.0001% to 0.002%, 0.0001% to 0.001%, 0.0002% to 0.015%, 0.0003% to 0.015%, 0.0004% to 0.015%, 0.0005% to 0.015%, 0.0006% to 0.015%, 0.0007% to 0.015%, 0.0008% to 0.015%, 0.0009% to 0.015%, 0.001% to 0.015%, 0.0011% to 0.015%, 0.0012% to 0.015%, 0.0013% to 0.015%, 0.0014% to 0.015%, 0.0002% to 0.001%, 0.0003% to 0.001%, 0.0004% to 0.001%, 0.0005% to 0.001%, 0.0006% to 0.001%, 0.0007% to 0.001%, 0.0008% to 0.001%, 0.0009% to 0.001%, 0.0002% to 0.0009%, 0.0002% to 0.0008%, 0.0002% to 0.0007%, 0.0002% to 0.0006%, 0.0002% to 0.0005%, 0.0002% to 0.0004%, 0.0002% to 0.0003%, 0.005% to 0.015%, 0.006% to 0.015%, 0.007% to 0.015%, 0.008% to 0.015%, 0.009% to 0.015%, 0.01% to 0.015%, 0.01% to 0.015%, 0.012% to 0.015%, 0.013% to 0.015%, 0.014% to 0.015%, 0.006% to 0.014%, 0.006% to 0.013%, 0.006% to 0.012%, 0.006% to 0.011%, 0.006% to 0.01%, 0.006% to 0.009%, 0.006% to 0.008%, or 0.006% to 0.007% as measured by Total Carbon analysis using Non-Dispersive Infrared Detection.

In some embodiments, an aluminum chloride (AlCl₃) precursor material has a low molybdenum impurity content. In some embodiments, the AlCl₃ precursor material comprises 0.01% to 2% by weight of the AlCl₅ impurity based on a total weight of the AlCl₃ precursor material, or any range or subrange between 0.01% to 2%. In some embodiments, the AlCl₃ precursor material comprises 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, or 0.01% to 0.05% by weight of the AlCl₅ impurity based on the total weight of the AlCl₅ precursor material. In some embodiments, the AlCl₅ precursor material comprises 0.05% to 1%, 0.1% to 1%, 0.2% to 1%, 0.3% to 1%, 0.4% to 1%, 0.5% to 1%, 0.6% to 1%, 0.7% to 1%, 0.8% to 1%, or 0.9% to 1% by weight of the AlCl₅ impurity based on the total weight of the AlCl₃ precursor material.

In some embodiments, the first ampoule 104, the second ampoule 106, and the internal support structures, such as trays, are made of 316L stainless steel that is electro-polished. The 316L stainless steel may be coated with a thin film of a more resistant material for each specific chemistry, e.g., nickel, aluminum oxide, etc. In some embodiments, a metal alloy material may be employed. Inconel, Hastelloy C276, C22, Alloy 20, etc. are examples of such alloys. Also, different materials may be employed. For example, the first ampoule 104, and the second ampoule 106, may be made of 316L stainless steel, and the internal support structure may be made of a more resistant alloy or coated with a more resistant alloy. It will be appreciated that the cabinet 102 may comprise only a single ampoule, or the cabinet 102 may comprise more than the first ampoule 104, the second ampoule 106. For example, in some embodiments, the cabinet 102 may comprise a third ampoule, a fourth ampoule, a fifth ampoule, a sixth ampoule, a seventh ampoule, an eighth ampoule, a ninth ampoule, a tenth ampoule, or more than ten ampoule.

The cabinet houses a manifold 108. The manifold 108 may be connected to a semiconductor tool. In some embodiments, the manifold 108 transports the first precursor material to a semiconductor tool 114 while the second ampoule 106 undergoes on-site purification. In some embodiments, the manifold 108 transports the precursor material to a semiconductor tool 114 while the first ampoule 104 undergoes on-site purification. In some embodiments, the semiconductor tool 114 may be located exterior to the cabinet 102. In some embodiments, the semiconductor tool 114 is located a distance from the cabinet 102.

The cabinet houses a first valve 110. The first valve 110 connects the first ampoule 104 to the manifold 108. In some embodiments, the first valve 110 has not been exposed to an external environment after the first valve has been exposed to the first precursor material. In some embodiments, the first valve has not been exposed to ambient conditions after the first valve has been exposed to the first precursor material.

The cabinet houses a first heater. In some embodiments, the first heater may be configured to heat the first ampoule. The first heater may heat the first ampoule to a target temperature.

In some embodiments, the first ampoule and the second ampoule are heated at or to a target temperature. In some embodiments, the target temperature is in a range of ambient to 500° C., or any range or subrange between ambient to 500° C.

Reaching the target temperature may be defined by a measurement point (in the first heater, on the first ampoule, or on the second ampoule) (i) going above a certain temperature, if the ampoule is being heated, (ii) going below a certain temperature, if the ampoule is being cooled, or (iii) oscillating within a range of the target temperature in either case. The target temperature may be in a range of +10° C., +5° C., +2° C., or +1° C.

The cabinet may house a second valve 112. The second valve 112 connects the second ampoule 106 to the manifold 108. In some embodiments, the second valve 112 is operated such that the first ampoule 104 delivers the first precursor material to the tool while the second ampoule 106 is purified. In some embodiments, the second valve 112 is operated such that the second ampoule 106 delivers the second precursor material to the tool while the first ampoule 104 is purified.

In some embodiments, the first valve 110 is operated such that the first ampoule 104 delivers the first precursor material to the manifold to distribute to the semiconductor tool while the second ampoule 106 is purified on-site. In some embodiments, the second valve 112 is operated such that the second ampoule 106 delivers the second precursor material to the manifold 108 to the tool while the first ampoule 104 is purified.

In some embodiments, a purge gas may be supplied by a purge gas supply to purge the manifold, the first valve, the second valve and other processing equipment, such as a heater and a filter, after being exposed to air during installation of the ampoule. In some embodiments, the purge gas is pumped through the manifold, the first valve, the second valve and other processing equipment, such as a heater and a filter to clean the processing equipment. In some embodiments, the purge cycle and pump cycle may be conducted with an automated cycle to purge and dry out the manifold, the first valve, the second valve and other processing equipment. In some embodiments, the purge cycle and the pump cycle may be alternated until the manifold, the first valve, the second valve and other processing equipment is clean and dried out. In some embodiments, the purge cycle and the pump cycle may be conducted at room temperature.

In some embodiments, the cabinet may house a pressure transducer. In some embodiments, the pressure transducer may be configured to monitor a pressure of the first ampoule and the second ampoule.

In some embodiments, the pressure of the first ampoule and the second ampoule may be reduced to remove a headspace vapor from the first ampoule and the second ampoule. The pressure reduction may be monitored with the pressure transducer. The headspace vapor may comprise any vapor present in the headspace of the first ampoule and the second ampoule. In some embodiments, the headspace vapor comprises at least one of a molybdenum precursor, a molybdenum impurity, an inert, a nonmolybdenum vapor or any combination thereof. In some embodiments, the headspace vapor comprises at least one of a tungsten precursor, a tungsten impurity, an inert, a non-tungsten vapor, or any combination thereof. In some embodiments, the headspace vapor comprises at least one of an aluminum trichloride precursor, an aluminum trichloride impurity, an inert, a nonaluminum trichloride vapor, or any combination thereof.

In some embodiments, the first ampoule and second ampoule pressure may be reduced. In some embodiments, the first ampoule and second ampoule may have a pressure in the range of 0.1 Torr to 3 Torr, or any range or subrange between 0.1 Torr and 3 Torr. In some embodiments, for example, the first ampoule and second ampoule have a pressure in the range of 0.25 Torr to 2.75 Torr, 0.5 Torr to 2.5 Torr, 0.75 Torr to 2.25 Torr, 1 Torr to 2 Torr, or 1.25 Torr to 1.75 Torr. In some embodiments, the first ampoule and second ampoule have a pressure in the range of 0.1 Torr to 2.75 Torr, 0.1 Torr to 2.5 Torr, 0.1 Torr to 2.25 Torr, 0.1 Torr to 2 Torr, 0.1 Torr to 1.75 Torr, 0.1 Torr to 1.5 Torr, 0.1 Torr to 1.25 Torr, 0.1 Torr to 1 Torr, 0.1 Torr to 0.75 Torr, 0.1 Torr to 0.5 Torr, or 0.1 Torr to 0.25 Torr. In some embodiments, the first ampoule and second ampoule have a pressure in the range of 0.25 Torr to 3 Torr, 0.5 Torr to 3 Torr, 0.75 Torr to 3 Torr, 1 Torr to 3 Torr, 1.25 Torr to 3 Torr, 1.5 Torr to 3 Torr, 1.75 Torr to 3 Torr, 2 Torr to 3 Torr, 2.25 Torr to 3 Torr, 2.5 Torr to 3 Torr, or 2.75 Torr to 3 Torr.

In some embodiments, the first ampoule and second ampoule have a pressure less than 0.1 Torr. In some embodiments, for example, the first ampoule and second ampoule have a pressure in the range of 0 Torr to 0.1 Torr, or any range or subrange between 0 Torr and 0.1 Torr. In some embodiments, the first ampoule and second ampoule have a pressure in the range of 0.01 Torr to 0.09 Torr, 0.02 Torr to 0.08 Torr, 0.03 Torr to 0.07 Torr, or 0.04 Torr to 0.06 Torr. In some embodiments, the first ampoule and second ampoule have a pressure in the range of 0.01 Torr to 0.1 Torr, 0.02 Torr to 0.1 Torr, 0.03 Torr to 0.1 Torr, 0.04 Torr to 0.1 Torr, 0.05 Torr to 0.1 Torr, 0.06 Torr to 0.1 Torr, 0.07 Torr to 0.1 Torr, 0.08 Torr to 0.1 Torr, or 0.09 Torr to 0.1 Torr. In some embodiments, the first ampoule and second ampoule have a pressure in the range of 0 Torr to 0.0.09 Torr, 0 Torr to 0.08 Torr, 0 Torr to 0.07 Torr, 0 Torr to 0.06 Torr, 0 Torr to 0.05 Torr, 0 Torr to 0.04 Torr, 0 Torr to 0.03 Torr, 0 Torr to 0.02 Torr, or 0 Torr to 0.01 Torr.

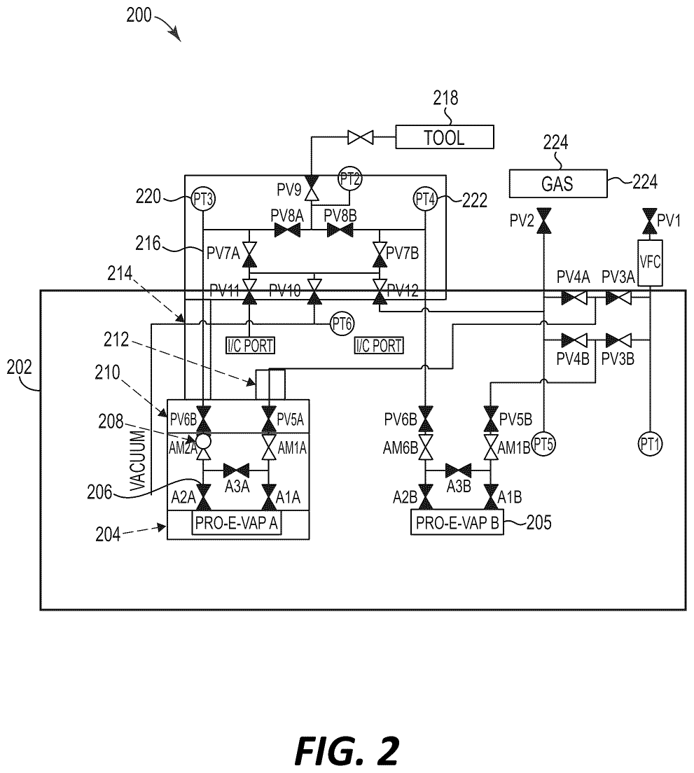

FIG. 2 is a schematic diagram of a system, according to some embodiments. System 200 generally functions in the same manner as system 100 except that system 200 comprises a controller. Specifically, the system 200 comprises a cabinet 202. The cabinet 202 houses a first ampoule 204 comprises a first precursor material and at least one first impurity. In some embodiments, the cabinet comprises a second ampoule 205. The second ampoule 205 comprises a second precursor material and at least one second impurity. The second ampoule 205 generally functions in the same manner as the first ampoule 204.

The cabinet houses a manifold 216. The manifold 216 may be connected to a semiconductor tool 218. The semiconductor tool 218 may be a vapor deposition apparatus.

The cabinet 202 comprises a first valve 206. The first valve 206 connects the first ampoule 204 to the manifold 218. In some embodiments, the first valve 206 has not been exposed to an external environment after the first valve has been exposed to the first precursor material.

In some embodiments, the cabinet comprises a second valve. The second valve connects the second ampoule to the manifold. In some embodiments, the second valve has not been exposed to an external environment after the second valve has been exposed to the second precursor material.

The cabinet 202 houses a first heater 214. In some embodiments, the first heater 214 is configured to heat the first ampoule 204.

In some embodiments, the cabinet may house a filter 208. The filter 208 may screen at least a portion of the at least one first impurity from the tool 218.

In some embodiments, the system 200 comprises a pressure transducer 220, 222. The pressure transducer 220, 222 may be configured to monitor the pressure of the first ampoule 204 and the second ampoule 205.

In some embodiments, the cabinet houses a controller. The controller (e.g., a microprocessor, a microcontroller, etc.) may be in communication with at least the first heater and the first valve 206. The controller may be configured to operate the first heater and the first valve so as to remove at least a portion of the at least one first impurity from the first ampoule. In some embodiments, the controller may be configured to heat the first ampoule to a temperature sufficient to obtain a vapor comprising at least a portion of the at least one first impurity.

In some embodiments, an air source 224 and a second heater 212 may be used to purge the first ampoule 204.

In some embodiments, the controller may be programmable. In some embodiments, the controller is in communication with the pressure transducer. In some embodiments, the controller is in communication with the first heater. In some embodiments, the controller is in communication with the manifold. In some embodiments, the controller is in communication with the first ampoule to deliver the first precursor material to the semiconductor tool.

In some embodiments, when the first precursor material is vaporized to produce a first precursor vapor, and when the first precursor vapor is delivered through the first valve 110 and the manifold 108 to the semiconductor tool 114, an amount of the at least one first impurity present in the first precursor vapor is less than an amount of at least one impurity present in a control precursor vapor delivered from a control ampoule to a semiconductor tool 114. In some embodiments, the control ampoule is connected to a control valve that has been exposed to an external environment after being exposed to the control precursor vapor.

In some embodiments, when the second precursor material is vaporized to produce a second precursor vapor and when the second precursor vapor is delivered through the second valve and the manifold to the tool, an amount of the at least one second impurity present in the second precursor vapor is less than an amount of at least one impurity present in a control precursor vapor delivered from a control ampoule to a tool, wherein the control ampoule is connected to a control valve that has been exposed to an external environment after being exposed to the control precursor vapor.

Some embodiments relate to a method. The method comprises the step of obtaining a cabinet. The cabinet comprises a first ampoule. The first ampoule comprises a first precursor material and at least one first impurity. The cabinet comprises a manifold. The manifold may be connectable to a tool. The cabinet comprises a first valve. The first valve connects the first ampoule to the manifold. In some embodiments, the first valve has not been exposed to an external environment after the first valve has been exposed to the first precursor material. The method comprises removing at least a portion of the at least one first impurity from the first ampoule. Prior to the step of removing, the first valve has not been exposed to an external environment after the first valve has been exposed to the first precursor material.

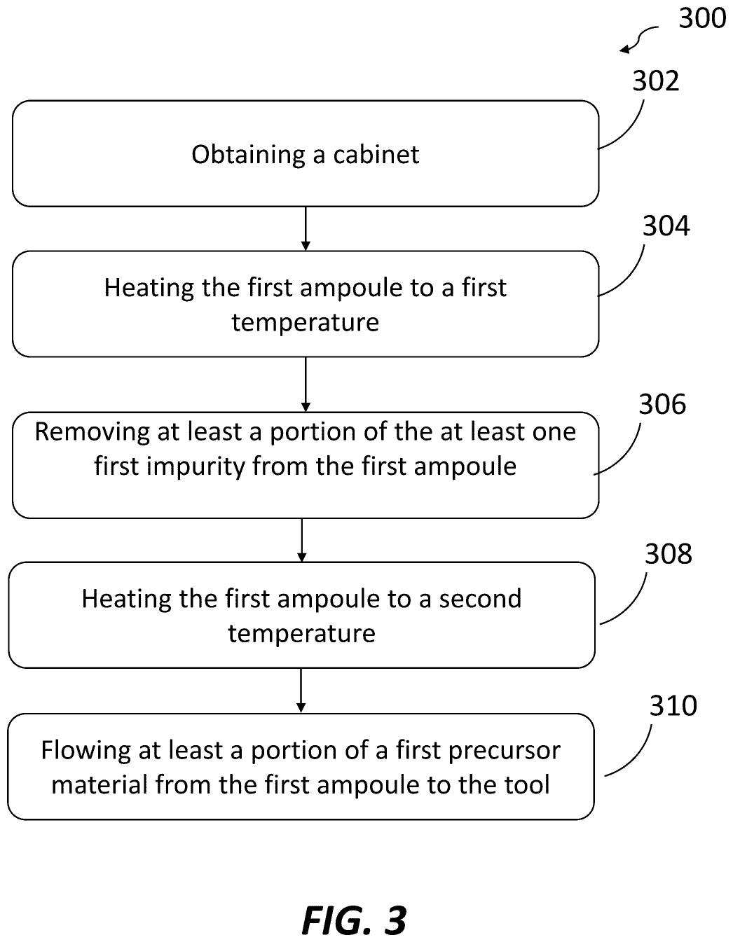

FIG. 3 is a flowchart of a method, according to some embodiments. As shown in FIG. 3, the method 300 comprises one or more of the following steps: obtaining 302 a cabinet; heating 304 a first ampoule to a first temperature; removing 306 at least a portion of the at least one first impurity from the first ampoule; heating 308 a first ampoule to a first temperature; and flowing 310 at least a portion of a first precursor material from the first ampoule to the tool. In some embodiments, the method 300 is implemented using any one or more of the systems disclosed herein which are incorporated by reference herein in their entirety and which, for simplicity, are not repeated here. For illustration purposes, method 300 describes the first ampoule. Method 300 may be implemented to describe the second ampoule, or any ampoule described in the system.

In some embodiments, the first valve is operated such that the second ampoule delivers the second precursor material to the tool while the first ampoule is purified on-site. In some embodiments, when the second material from the second ampoule is removed, the first ampoule has at least a portion of the at least one first impurity from the first ampoule removed.

At step 302, the method 300 comprises obtaining a cabinet. The cabinet generally functions the same as in system 100 and 200. The cabinet houses a first ampoule. The first ampoule comprises a first precursor material and at least one first impurity. The cabinet houses a second ampoule. The second ampoule comprises a second precursor material. In some embodiments, the second ampoule comprises at least one second impurity. The second ampoule generally functions in the same manner as the first ampoule. The cabinet houses a manifold connectable to a tool. The tool may be outside the cabinet. The cabinet comprises a first valve. The first valve connects the first ampoule to the manifold. In some embodiments, the first valve has not been exposed to an external environment after the first valve has been exposed to the first precursor material. In some embodiments, the cabinet comprises a second valve. The second valve connects the second ampoule to the manifold.

In some embodiments, the step of removing at least a portion of the at least one first impurity from the first ampoule, the method 300 comprises the step of opening the first valve, so as to remove at least a portion of a vapor from the first ampoule. In some embodiments, the vapor comprises the at least one first impurity. In some embodiments, the step of opening the first valve comprises exposing the first ampoule to an external air source. In some embodiments, the step of opening the first valve further includes pumping the external air source through the first valve.

In some embodiments, the step of removing at least a portion of the at least one first impurity from the first ampoule, the method 300 comprises the step of evacuating the first ampoule under vacuum, so as to remove at least a portion of a vapor from the first ampoule. In some embodiments, the vapor comprises the at least one first impurity. In some embodiments, the step of evacuating comprises the reduction of pressure of the first ampoule. In some embodiments, the reduction of pressure is achieved by pumping at least a portion of the vapor from the first ampoule. In some embodiments, the step of evacuating, is performed at room temperature.

As the pressure is reduced, method 300 may comprise monitoring the pressure of the first ampoule until the first ampoule pressure is in a range of 0 Torr to 3 Torr. The pressure may be monitored using a pressure transducer.

In some embodiments, the reduced pressure of the first ampoule may be in the range of 0.1 Torr to 3 Torr, or any range or subrange between 0.1 Torr and 3 Torr. In some embodiments, for example, the reduced pressure of the first ampoule may be in the range 0.25 Torr to 2.75 Torr, 0.5 Torr to 2.5 Torr, 0.75 Torr to 2.25 Torr, 1 Torr to 2 Torr, or 1.25 Torr to 1.75 Torr. In some embodiments, the reduced pressure of the first ampoule may be in the range of 0.1 Torr to 2.75 Torr, 0.1 Torr to 2.5 Torr, 0.1 Torr to 2.25 Torr, 0.1 Torr to 2 Torr, 0.1 Torr to 1.75 Torr, 0.1 Torr to 1.5 Torr, 0.1 Torr to 1.25 Torr, 0.1 Torr to 1 Torr, 0.1 Torr to 0.75 Torr, 0.1 Torr to 0.5 Torr, or 0.1 Torr to 0.25 Torr. In some embodiments, the reduced pressure of the first ampoule may be in the range of 0.25 Torr to 3 Torr, 0.5 Torr to 3 Torr, 0.75 Torr to 3 Torr, 1 Torr to 3 Torr, 1.25 Torr to 3 Torr, 1.5 Torr to 3 Torr, 1.75 Torr to 3 Torr, 2 Torr to 3 Torr, 2.25 Torr to 3 Torr, 2.5 Torr to 3 Torr, or 2.75 Torr to 3 Torr.

In some embodiments, the reduced pressure of the first ampoule may be less than 0.1 Torr. In some embodiments, for example, the reduced pressure of the first ampoule may be in the range 0 Torr to 0.1 Torr, or any range or subrange between 0 Torr and 0.1 Torr. In some embodiments, the reduced pressure of the first ampoule may be in the range of 0.01 Torr to 0.09 Torr, 0.02 Torr to 0.08 Torr, 0.03 Torr to 0.07 Torr, or 0.04 Torr to 0.06 Torr. In some embodiments, the reduced pressure of the first ampoule may be in the range of 0.01 Torr to 0.1 Torr, 0.02 Torr to 0.1 Torr, 0.03 Torr to 0.1 Torr, 0.04 Torr to 0.1 Torr, 0.05 Torr to 0.1 Torr, 0.06 Torr to 0.1 Torr, 0.07 Torr to 0.1 Torr, 0.08 Torr to 0.1 Torr, or 0.09 Torr to 0.1 Torr. In some embodiments, the reduced pressure of the first ampoule may be in the range of 0 Torr to 0.09 Torr, 0 Torr to 0.08 Torr, 0 Torr to 0.07 Torr, 0 Torr to 0.06 Torr, 0 Torr to 0.05 Torr, 0 Torr to 0.04 Torr, 0 Torr to 0.03 Torr, 0 Torr to 0.02 Torr, or 0 Torr to 0.01 Torr.

In some embodiments, if the pressure transducer is greater than 0.5 Torr for less than 20 minutes, then the method 300 may comprise continuing to reduce or draw down the pressure of the first ampoule by pumping ampoule with the external pump. In some embodiments, if the pressure transducer is less than 0.5 Torr for less than 20 minutes, then the method 300 may proceed to step 302.

In some embodiments, the step of removing at least a portion of the at least one first impurity from the first ampoule, the method 300 comprises the steps of heating 304 the first ampoule to a temperature sufficient to obtain a vapor comprising at least a portion of the at least one first impurity and removing the vapor from the first ampoule.

In some embodiments, the step of removing comprises heating the first ampoule to a first temperature sufficient to produce a vapor having a vapor pressure that is 1 to 1.2 times a theoretical vapor pressure of the first precursor material. In some embodiments, the vapor comprises the at least one first impurity. The method further comprises removing the vapor from the first ampoule.

In some embodiments, the first temperature to produce a vapor is in a range of 60° C. to 170° C., or any range or subrange between 60° C. to 170° C. In some embodiments, the first temperature is in a range of 60° C. to 160° C., 60° C. to 150° C., 60° C. to 140° C., 60° C. to 130° C., 60° C. to 120° C., 60° C. to 110° C., 60° C. to 100° C., 60° C. to 90° C., 60° C. to 80° C., 60° C. to 70° C., 70° C. to 170° C., 80° C. to 170° C., 90° C. to 170° C., 100° C. to 170° C., 110° C. to 170° C., 120° C. to 170° C., 130° C. to 170° C., 140° C. to 170° C., 150° C. to 170° C., 160° C. to 170° C., 100° C. to 160° C., 120° C. to 160° C., 140° C. to 160° C., 120° C. to 150° C., 120° C. to 140° C., or 110° C. to 150° C.

In some embodiments, the MoCl₅ precursor material, when contained in the first ampoule, has, when the first ampoule is maintained at a temperature of 70° C. to 240° C. (or any range or subrange therebetween), a theoretical vapor pressure of less than 1.2 times a calculated a vapor pressure of MoCl₅ determined according to the formula:

$$Log P ( Torr ) = 10.976 - \frac{4354}{T ( K )}$$

In some embodiments, the MoO₂Cl₅ precursor material, when contained in the first ampoule, has, when the first ampoule is maintained at a temperature of 70° C. to 240° C. (or any range or subrange therebetween), a theoretical vapor pressure of less than 1.2 times a calculated a vapor pressure of MoO₂Cl₅ determined according to the formula:

$$Log P ( Torr ) = 12.72 - \frac{4270}{T ( K )}$$

In some embodiments, the WCl₅ precursor material, when contained in the first ampoule, has, when the first ampoule is maintained at a temperature of 70° C. to 240° C. (or any range or subrange therebetween), a theoretical vapor pressure of less than 1.1 times a calculated vapor pressure of WCl₅ determined according to the formula:

$$Log P ( Torr ) = 11.119 + \frac{- 4634}{T ( K )}$$

In some embodiments, the AlCl₅ precursor material, when contained in the first ampoule, has, when the first ampoule is maintained at a temperature of 70° C. to 240° C. (or any range or subrange therebetween), a theoretical vapor pressure of less than 1.1 times a calculated vapor pressure of AlCl₅ determined according to the formula:

$$Log P ( Torr ) = 15.88462 - \frac{5900.71}{T ( K )}$$

In some embodiments, the step of heating may be at least 4 hours. In some embodiments, for example, and without limitation, the step of heating is in the range of 4 hours to 6 hours, or any range or subrange between 4 hours and 6 hours. In some embodiments, the first target time is in the range of 4 hours to 5.5 hours, 4 hours to 5 hours, or 4 hours to 4.5 hours. In some embodiments, the first target time is in the range of 4.5 hours to 6 hours, 5 hours to 6 hours, or 5.5 hours to 6 hours.

In method 300, if the vapor pressure is in the range of 1 to 1.2 times the theoretical vapor pressure of the first precursor material, then the method may proceed to step 306 of removing at least a portion of the at least one first impurity from the first ampoule.

In some embodiments, when heating the first ampoule, if the vapor pressure is greater than 1.2 times the theoretical vapor pressure of the first precursor material, then the method 300 comprises the step of reducing the pressure of the first ampoule to produce a vapor having a vapor pressure that is 1 to 1.2 times the theoretical vapor pressure of the first precursor material. Typically, in most instances, the vapor pressure is not within the range of 1 to 1.2 times the theoretical vapor pressure of the first precursor material. In such instances, the method selected to produce a vapor having a vapor pressure that is 1 to 1.2 times the theoretical vapor pressure of the first precursor material depends on the first precursor material.

In some embodiments, for example, MoO₂Cl₂ precursor material, and AlCl₃ precursor material, to produce a vapor having a vapor pressure that is 1 to 1.2 the theoretical vapor pressure of the first precursor material, is achieved by waiting for a sufficient time.

In some embodiments, the sufficient time is at least 4 hours. In some embodiments, for example, and without limitation, the sufficient time is in the range of 4 hours to 6 hours, or any range or subrange between 4 hours and 6 hours. In some embodiments, the sufficient time is in the range of 4 hours to 5.5 hours, 4 hours to 5 hours, or 4 hours to 4.5 hours. In some embodiments, the sufficient time is in the range of 4.5 hours to 6 hours, 5 hours to 6 hours, or 5.5 hours to 6 hours.

In some embodiments, for example, the AlCl₅ precursor material, after waiting for the sufficient time, if the vapor pressure of the vapor has been reduced by at least 0.1 times the theoretical vapor pressure in a second cycle, then the step of heating the first ampoule to a first temperature sufficient to produce a vapor having a vapor pressure that is 1 to 1.2 times the theoretical vapor pressure of the precursor material, may be repeated, among other steps, before cooling the first ampoule to ambient temperature, described herein.

In some embodiments, the method 300 for MoO₂Cl₂ precursor material, and AlCl₅ precursor material, further comprises the step of cooling the first ampoule to ambient temperature and waiting a sufficient time. In some embodiments, the sufficient time is at least 4 hours. In some embodiments, for example, and without limitation, the sufficient time is in the range of 4 hours to 6 hours, or any range or subrange between 4 hours and 6 hours. In some embodiments, the sufficient time is in the range of 4 hours to 5.5 hours, 4 hours to 5 hours, or 4 hours to 4.5 hours. In some embodiments, the sufficient time is in the range of 4.5 hours to 6 hours, 5 hours to 6 hours, or 5.5 hours to 6 hours.

In some embodiments, the method 300 for MoO₂Cl₂ precursor material, and AlCl₅ precursor material, the step of reducing a pressure of the first ampoule at ambient temperature, described herein, is repeated and the steps of method 300 is followed until the pressure is in the range of 1 to 1.2 times the theoretical vapor pressure, then the method 300 comprises the step of removing the vapor from the first ampoule.

In some embodiments, if the pressure of the first ampoule is greater than 1.2 times the vapor pressure of the first precursor material, MoO₂Cl₂ precursor material, MoCl₅ precursor material, and WCl₅ precursor material, the step of reducing the pressure of the first ampoule to a range of 1 to 1.2 vapor pressure, is achieved by pumping the first ampoule for a sufficient time. In some embodiments, the sufficient time is in the range of 20 seconds to 1 minute, or any range or subrange between 20 seconds and 1 minute. In some embodiments, for example and without limitation, the sufficient time is in the range of 25 seconds to 55 seconds, 30 seconds to 50 seconds, or 35 seconds to 45 seconds. In some embodiments, for example and without limitation, the sufficient time is in the range of 20 seconds to 55 seconds, 20 seconds to 50 seconds, 20 seconds to 45 seconds, 20 seconds to 40 seconds, 20 seconds to 35 seconds, 20 seconds to 30 seconds, or 20 seconds to 25 seconds. In some embodiments, for example and without limitation, the sufficient time is in the range of 25 seconds to 1 minute, 30 seconds to 1 minute, 35 seconds to 1 minute, 40 seconds to 1 minute, 45 seconds to 1 minute, 50 seconds to 1 minute, or 55 seconds to 1 minute.

In some embodiments, for the MoO₂Cl₂ precursor material, MoCl₅ precursor material, and WCl₅ precursor material, after pumping the first ampoule for a sufficient time, the method 300 comprises an additional waiting period. In some embodiments, the additional waiting period is in the range of 1 minute to 3 minutes, or any range or subrange between 1 minute and 3 minutes. In some embodiments, for example and without limitation, the additional waiting period is in the range of 1.25 minutes to 2.75 minutes, 1.5 minutes to 2.5 minutes, or 1.75 minutes to 2.25 minutes. In some embodiments, the additional waiting period is in the range of 1 minute to 2.75 minutes, 1 minute to 2.5 minutes, 1 minute to 2.25 minutes, 1 minute to 2 minutes, 1 minute to 1.75 minutes, 1 minute to 1.5 minutes, or 1 minute to 1.25 minutes. In some embodiments, the additional waiting period time is in the range of 1.25 minutes to 3 minutes, 1.5 minutes to 3 minutes, 1.75 minutes to 3 minutes, 2 minutes to 3 minutes, 2.25 minutes to 3 minutes, 2.5 minutes to 3 minutes, or 2.75 minutes to 3 minutes.

In some embodiments, the pumping of the first ampoule may be for at least 2 cycles until the pressure is in the range of 1 to 1.2 times the theoretical vapor pressure. In some embodiments, the pumping of the first ampoule may be for 1 cycle to 15 cycles, or any range or subrange between 1 cycle and 15 cycles. In some embodiments, for example and without limitation, the pumping of the first ampoule may be for 2 cycles to 14 cycles, 3 cycles to 13 cycles, 4 cycles to 12 cycles, 5 cycles to 11 cycles, 6 cycles to 10 cycles, or 7 cycles to 9 cycles. In some embodiments, the pumping of the first ampoule may be for 2 cycles to 15 cycles, 3 cycles to 15 cycles, 4 cycles to 15 cycles, 5 cycles to 15 cycles, 6 cycles to 15 cycles, 7 cycles to 15 cycles, 8 cycles to 15 cycles, 9 cycles to 15 cycles, 10 cycles to 15 cycles, 11 cycles to 15 cycles, 12 cycles to 15 cycles, 13 cycles to 15 cycles, or 14 cycles to 15 cycles. In some embodiments, the pumping of the first ampoule may be for 1 cycle to 14 cycles, 1 cycle to 13 cycles, 1 cycle to 12 cycles, 1 cycle to 11 cycles, 1 cycle to 10 cycles, 1 cycle to 9 cycles, 1 cycle to 8 cycles, 1 cycle to 7 cycles, 1 cycle to 6 cycles, 1 cycle to 5 cycles, 1 cycle to 4 cycles, 1 cycle to 3 cycles, or 1 cycle to 2 cycles.

In some embodiments, the method 300 for MoO₂Cl₂ precursor material, MoCl₅ precursor material, and WCl₅ precursor material, if the pressure is in the range of 1 to 1.2 times the theoretical vapor pressure, then the method 300 comprises the step of removing the vapor from the first ampoule.

In some embodiments, the step of removing is performed until a vapor pressure until a vapor pressure of a vapor removed from the first ampoule is within 20% of a theoretical vapor pressure of the first precursor material.

In some embodiments, the method 300 comprises the step of cooling the first ampoule to a second temperature. In some embodiments, the second temperature is less than the first temperature. In some embodiments, the second temperature is ambient temperature. The step of cooling may be after the step of heating. In some embodiments, method 300 comprises cooling the first ampoule for a sufficient time until the pressure of the first ampoule is in the range of 0 Torr to 0.5 Torr, or any range or subrange between 0 Torr and 0.5 Torr. In some embodiments, the cooled first ampoule may have a pressure in the range of 0 Torr to 0.4 Torr, 0 Torr to 0.3 Torr, 0 Torr to 0.2 Torr, or 0 Torr to 0.1 Torr. In some embodiments, the cooled first ampoule may have a pressure in the range of 0.1 Torr to 0.5 Torr, 0.2 Torr to 0.5 Torr, 0.3 Torr to 0.5 Torr, or 0.4 Torr to 0.5 Torr. In some embodiments, the pressure of the first ampoule is monitored using the pressure transducer.

In some embodiments, the sufficient time is at least 4 hours. In some embodiments, for example, and without limitation, the sufficient time is in the range of 4 hours to 6 hours, or any range or subrange between 4 hours and 6 hours. In some embodiments, the sufficient time is in the range of 4 hours to 5.5 hours, 4 hours to 5 hours, or 4 hours to 4.5 hours. In some embodiments, the sufficient time is in the range of 4.5 hours to 6 hours, 5 hours to 6 hours, or 5.5 hours to 6 hours.

In some embodiments, prior to the step of removing 306, the first valve has not been exposed to an external environment after the first valve has been exposed to the first precursor material.

At step 306, the method 300 comprises the step of removing at least a portion of the at least one first impurity from the first ampoule. In some embodiments, at least a portion of the at least one first impurity from the first ampoule is removed with a reduction in pressure of the first ampoule in the range of 0.1 Torr to 3 Torr.

In some embodiments, after the pressure of the first ampoule is less than 0.5 Torr, the first ampoule is ready for use. The first ampoule is purified and ready to flow the first precursor material to the tool.

At step 308, the method 300 comprises the step of heating the first ampoule to a second temperature. In some embodiments, the second temperature is an operating temperature at the customer site.

At step 310, the method 300 comprises the step of flowing at least a portion of a first precursor material from the first ampoule to the tool. The first ampoule, having been purified, for example, at the customer site, may be free of the at least one first impurity. In some embodiments, at least 70% of the first precursor material may flow from the first ampoule to the tool. For example, in some embodiments, the step of flowing comprises flowing the at least a portion of the first precursor material in a range of 75% to 95%, or 80% to 90%. In some embodiments, the step of flowing comprises flowing the at least a portion of the first precursor material in a range of 70% to 99%, or any range or subrange between 70% and 99%. In some embodiments, the step of flowing comprises flowing the at least a portion of the first precursor material in a range of 70% to 95%, 70% to 90%, 70% to 85%, 70% to 80%, or 70% to 75%. In some embodiments, the step of flowing comprises flowing the at least a portion of the first precursor material in a range of 75% to 99%, 80% to 99%, 85% to 99%, 90% to 99%, or 95% to 99%.

In some embodiments, the first valve, after being connected to the first ampoule and after being exposed to the first precursor material, is not disconnected from the first ampoule so as to be exposed to the external environment.

In some embodiments, prior to the step of removing, the first valve has not been exposed to an external environment after being exposed to the first precursor material.

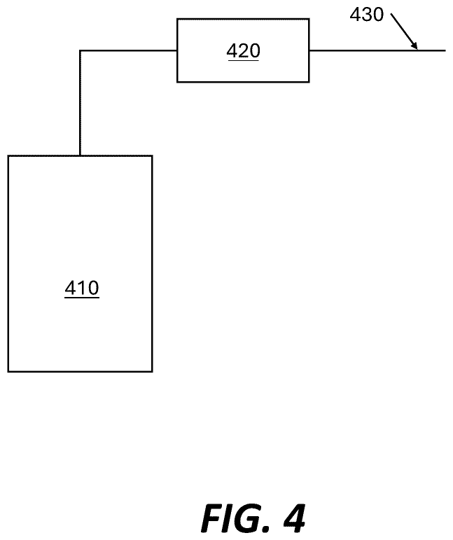

FIG. 4 is schematic diagram of a system, according to some embodiments.

FIG. 4 includes a delivery ampoule 410 and a filter 420 between the delivery ampoule 410 and line 430 to a processing tool. The filter 420 may be within a delivery cabinet. In some embodiments, the filter 420 is internal to the ampoule 410. In other embodiments, the filter 420 is located on a line 430 between the ampoule 410 and the processing tool. The line 430 is a delivery line used to delivery vaporized precursor from the ampoule 410 to the processing tool. In some embodiments, the filter 420 is able to be replaced without removing or damaging the line 430. The filter 420 may be replaced on a regular schedule, for example, after every ampoule 410 is replaced or after multiple ampoules 410 are replaced. In some embodiments, the filter 420 is replaced based on an operation time of the processing tool. In some embodiments, the filter 420 replaced after a fixed number of days.

The filter 420 may include a single filter 420 or multiple filters 420 in series or parallel. In some embodiments, the filter 420 has a pore size between 2 micrometer (μm) to 10 μm, inclusive. In one embodiment, the filter 420 is able to remove particles down to 3 nanometers. The filter 420 may use corrosion resistant materials to enhance compatibility with the vaporized precursor and reduce particulate formation. Exemplary corrosion resistant materials for use in the filter include nickel, stainless steel, nickel-based superalloys such as the Hastelloy alloys, and polytetrafluoroethylene (PTFE). The membrane of the filter 420 may be made from these same materials or from other chemically resistant materials. In some examples, internal components of the filter 420 are surface modified to enhance chemical compatibility. The filter 420 may be an inline filter 420, for example, a gasket filter. On example of suitable, commercially available filters is the Wafergard® series produced by Entegris, Inc. of Billerica, MA.

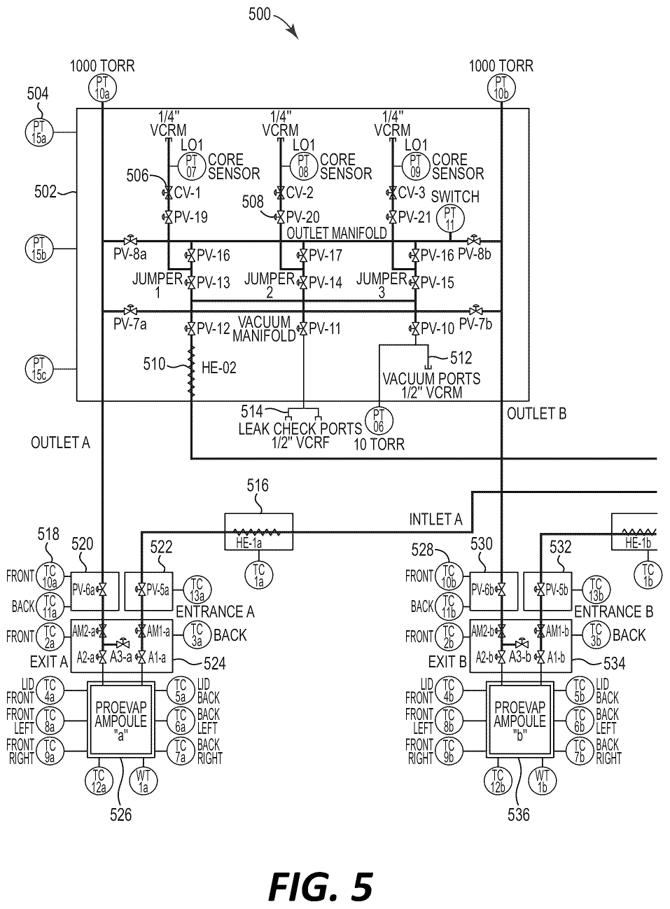

FIG. 5 is a schematic diagram of a system 500, according to some embodiments. The system 500 includes a manifold 502, which includes a vacuum manifold and an outlet manifold. The manifold 502 includes a number of valves 506, 508. The valves 506, 508 are controllable to selectively connect the ampoules 526, 536 to a vacuum source, for example, via vacuum port 512. The valves 506, 508 are controllable to selectively connect the ampoules 526, 536 to the outlet manifold to supply the lines out (LO1). The valves 506, 508 include control valves (CV) 506 and pneumatic valves (PV) 508. The system 500 includes multiple pressure transmitters (PT) 504. The system 500 also includes multiple temperature controllers (TC) 518. Heat exchangers 510, 516 are used to adjust the temperature of lines providing material to or form the system 500. In one embodiment, heat exchanger 516 is used to heat carrier gas being provided to the ampoule 526. In some examples, the heat exchangers 510, 516 may be heating coils or tape around the associated lines.

A single vacuum port 512 may be provided or multiple vacuum ports 512 may be provided as part of the system 500. The vacuum port 512 supplies vacuum to the system 500 from an external vacuum source. The vacuum port 512 in some embodiments may include a cooled trap (not shown) to capture material from the system 500. The system may also include one or more leak check ports 514. The leak check port 514 may be used to check the system 500 for leaks by monitoring pressure over time.

On the line from the ampoule 526 to the manifold 502, there is a temperature controller 518 in an enclosure 520 around a pneumatic valve. This temperature controller 518 may be used to heat the pneumatic valve and/or the line to prevent condensation of the precursor in the line. In some embodiments, the temperature of the line between the ampoule 526 and the manifold 502 is greater than the temperature of the ampoule 526. A similar enclosure 522 and temperature controller is around a pneumatic valve on the carrier gas feed into the ampoule 526. This enclosure 522 and temperature controller help regulate the temperature of the carrier gas provided to the ampoule 526. Similar elements temperature controller 528, enclosure 530, enclosure 532, and control manifold 534 are located on the other ampoule 536.

Each ampoule 526, 536 has an associated control manifold 524, 534 of valving. In some embodiments, the control manifold 524, 534 may sit on top of the associated ampoule 526, 536. In some embodiments, the control manifold 524, 534 is integrated with the associated ampoule 526, 536 and is not generally separated from the associated ampoule 526, 536 during use, attachment, or removal of the associated ampoule 526, 536 from the system 500.

The system 500 shown in FIG. 5 includes multiple ampoules 526, 536 to provide a given precursor to a semiconductor tool. The use of multiple ampoules 526, 536 allows for an uninterrupted supply of the precursor as when a first ampoule 526 runs out of precursor to supply, a second ampoule 536 can provide the desired precursor. The system 500 is capable of removing contaminants from one ampoule 536 while another ampoule 526 is delivering precursor to the semiconductor tool.

The ampoules 526, 536 have associated heaters and temperature sensors. Each ampoule 526, 536 may have carrier gas provided to the ampoule at a respective entrance. The carrier gas may be temperature modified prior to introduction into the ampoule. Flow rate of the carrier gas may be regulated using valve. A bypass allows for carrier gas to optionally flow into the system bypassing the ampoule. This may be useful for clearing lines of precursor. The outlet line from the ampoule may include a number of valves before connecting to a manifold. This particular embodiment includes an outlet manifold which includes multiple lines out which may be used to supply precursor to the same or different portions of a semiconductor tool. The outlet line may include an associated sensor or multiple sensors. In some embodiments, the sensors include a pressure sensor. In some embodiments, the sensors include a temperature sensor. In one embodiment, the different lines out supply different chambers in a semiconductor tool. In another embodiment, the different lines out supply different semiconductor tools. The vacuum manifold allows vacuum to be applied to portions of the various lines.

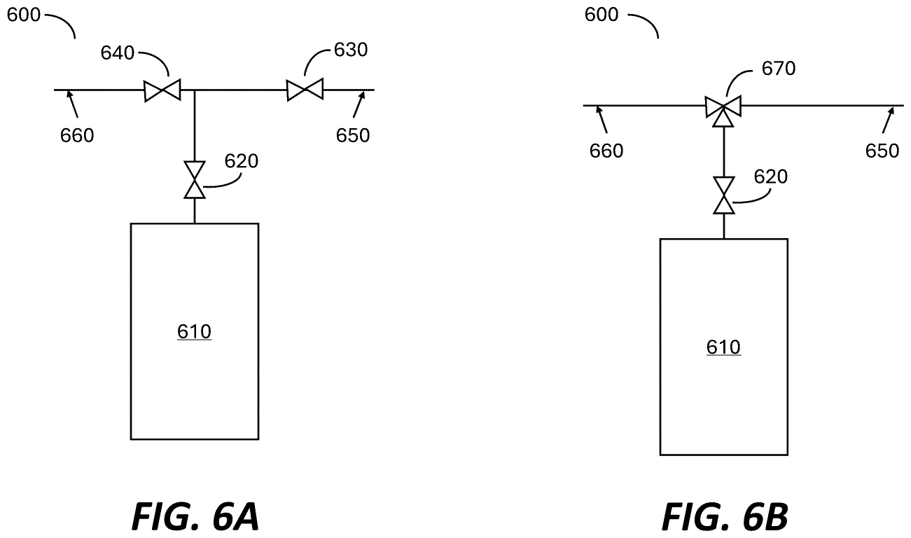

FIGS. 6A and 6B are schematic diagrams of systems, according to some embodiments. In FIG. 6A, the system 600 includes an ampoule 610 which contains precursor material. The precursor material may be a solid precursor material. In some embodiments, the precursor is a molybdenum precursor, such as MoO₂Cl₂, MoOCl₄, MoCl₅, or MoCl₆. It can be challenging to completely purify molybdenum precursors. In some embodiments, the contaminant may include other molybdenum precursors. Contaminants may also include hydrates or reaction products of the molybdenum precursors. In other instances, the contaminants may include other metal halides or oxyhalides. For example, tungsten halides are often mixed with molybdenum precursors at very low levels but in sufficient quantity to be problematic.

The ampoule 610 delivers vaporized precursor to a line 650 connected to a semiconductor processing tool. In some embodiments, the semiconductor processing tool is a chemical vapor deposition (CVD) tool, an atomic layer deposition (ALD) tool, or other deposition tool. Any suitable tool that would use the vaporized precursor may be used as the semiconductor processing tool and a wide range of such tools are known in the art.

The line 650 to the semiconductor processing tool includes multiple valves 620, 630, and 640. The valves 620 and 630 allow isolation of a portion of the delivery line between the ampoule 610 and the semiconductor processing tool. Vaporized material can be captured in this isolated portion. Valve 640 can then be opened to remove this vaporized material. Valve 640 may be connected to a vacuum or low pressure line 660. The line 660 coming off of valve 640 may include a trap or similar device to capture the vaporized material. In one embodiment, a trap is a lower temperature component to condense the vaporized material. As discussed above, some contaminants have a higher vapor pressure than the used molybdenum precursors. By heating and selectively venting the ampoule, the presence of these contaminants in the stream of delivered precursor can be significantly reduced. This may improve the operation of the semiconductor deposition tool. In some embodiments, the isolatable portion of the line 650 includes a pressure sensor (not shown). In some embodiments, the pressure sensor is used to determine the vapor pressure and compare it with a known or calculated value of the vapor pressure of the pure precursor. Venting may be conducted based on a comparison of the measured vapor pressure and the known or calculated value. Venting may not be needed; may be performed once; or may be performed multiple times. This may depend on the amount of contaminant in the precursor material in the ampoule 610.

In some designs, in may be possible to forgo the valve 620 nearest to the ampoule 610 and pull vacuum or low pressure on the contents of the ampoule 610. This approach may increase the quantity of solids or particulate entrained in the gas stream delivered to the semiconductor deposition tool. Accordingly, the inclusion of the valve 620 serves a useful function in the described system 600.

FIG. 6B is similar to FIG. 6A and includes an ampoule 610, a valve 620, a line 650 connected to a semiconductor tool, a line 660 connected to a vacuum or low pressure. Instead of valves 630 and 640, FIG. 6B uses a three-way valve 670 to perform the functions of isolating a portion of the line 650 and venting the isolated vaporized material to line 660.

### Example 1

An on-site purification process for a system with an ampoule having MoO₂Cl₂ precursor material was performed. The ampoule featured carbon trays. The system modeled FIG. 2. The process included the installation of the ampoule having the MoO₂Cl₂ precursor material. The ampoule was then pumped, and the pigtail valves were purged. The ampoule was then pumped until the pressure of the ampoule was less than 0.1 Torr. The pressure was monitored while pumping. If the pressure was above 0.5 Torr for less than 20 minutes, the ampoule was pumped again until the pressure was less than 0.1 Torr.

The ampoule was heated to the system operating temperature for 4 hours. If the vapor pressure of the MoO₂Cl₂ precursor material was greater than 1.2 times a theoretical vapor pressure of the MoO₂Cl₂ precursor material, the ampoule was held at the operating temperature for an additional 4 hours. The ampoule was then cooled to ambient temperature. The ampoule temperature was held at ambient for 4 hours. The ampoule was then pumped until the pressure was less than 0.1 Torr and the method was repeated until, when heated, the vapor pressure of the MoO₂Cl₂ precursor material was in the range of 1 to 1.2 times the theoretical vapor pressure. The ampoule was then cooled to ambient temperature and held at ambient temperature for 4 hours. If the pressure of the ampoule was greater than 0.5 Torr, the method was pumped until the pressure was less than 0.1 Torr. The method was repeated until the ampoule when cooled at ambient temperature, pressure was less than 0.5 Torr. At less than 0.5 Torr, the ampoule was purified and ready for use.

### Example 2

An on-site purification process for a system with an ampoule having MoO₂Cl₂ precursor material was performed. The ampoule featured carbon trays. The system modeled FIG. 2. The process included the installation of the ampoule having the MoO₂Cl₂ precursor material. The ampoule was then pumped, and the pigtail valves were purged. The ampoule was then pumped until the pressure of the ampoule was less than 0.1 Torr. The pressure was monitored while pumping. If the pressure was above 0.5 Torr for less than 20 minutes, the ampoule was pumped again until the pressure was less than 0.1 Torr.

The ampoule was heated to the system operating temperature for 4 hours. If the vapor pressure of the MoO₂Cl₂ precursor material was greater than 1.2 times a theoretical vapor pressure of the MoO₂Cl₂ precursor material, the ampoule was pumped for 30 seconds, or pumped until the vapor pressure was 0.8 times the theoretical vapor pressure. The ampoule was held steady for 120 seconds and the method was repeated to determine whether the vapor pressure was greater than 1.2 times a theoretical vapor pressure of the MoO₂Cl₂ precursor material. If the vapor pressure was in the range of 1 to 1.2 times the theoretical vapor pressure, the ampoule was then cooled to ambient temperature and held at ambient temperature for 4 hours. If the pressure of the ampoule was greater than 0.5 Torr, the method was pumped until the pressure was less than 0.1 Torr. The method was repeated until the ampoule when cooled at ambient temperature, pressure was less than 0.5 Torr. At less than 0.5 Torr, the ampoule was purified and ready for use.

### Example 3

An on-site purification process for a system with an ampoule having AlCl₃ precursor material was performed. The ampoule featured carbon trays and aluminum trays. The system modeled FIG. 2. The process included the installation of the ampoule having the AlCl₅ precursor material. The ampoule was then pumped, and the pigtail valves were purged. The ampoule was then pumped until the pressure of the ampoule was less than 0.1 Torr. The pressure was monitored while pumping. If the pressure was above 0.5 Torr for less than 20 minutes, the ampoule was pumped again until the pressure was less than 0.1 Torr.

The ampoule was heated to the system operating temperature for 4 hours. If the vapor pressure of the AlCl₅ precursor material was greater than 1.2 times a theoretical vapor pressure of the AlCl₅ precursor material, the ampoule was held at the operating temperature for an additional 4 hours. If the vapor pressure of the AlCl₅ precursor material reduced by at least 0.1 times the theoretical vapor pressure after the additional 4 hours, and the vapor pressure of the AlCl₅ precursor material was in the range of 1 to 1.2 times the theoretical vapor pressure, the ampoule was then cooled to ambient temperature. If the vapor pressure of the AlCl₅ precursor material had not been reduced by at least 0.1 times the theoretical vapor pressure after the additional 4 hours, the ampoule was cooled to ambient temperature and was held at ambient temperature for 4 hours. The ampoule was then pumped until the pressure was less than 0.1 Torr and the method was repeated until, when heated, the vapor pressure of the MoO₂Cl₂ precursor material was in the range of 1 to 1.2 times the theoretical vapor pressure. The ampoule was then cooled to ambient temperature and held at ambient temperature for 4 hours. If the pressure of the ampoule was greater than 0.5 Torr, the method was pumped until the pressure was less than 0.1 Torr. The method was repeated until the ampoule when cooled at ambient temperature, pressure was less than 0.5 Torr. At less than 0.5 Torr, the ampoule was purified and ready for use.

### Example 4

An on-site purification process for a system with an ampoule having MoCl₅ precursor material was performed. The ampoule featured stainless steel trays. The systems modeled FIG. 2. The process included the installation of the ampoule having the MoCl₅ precursor material. The ampoule was then pumped, and the pigtail valves were purged. The ampoule was then pumped until the pressure of the ampoule was less than 0.1 Torr. The pressure was monitored while pumping. If the pressure was above 0.5 Torr for less than 20 minutes, the ampoule was pumped again until the pressure was less than 0.1 Torr.

The ampoule was heated to the system operating temperature for 4 hours. If the vapor pressure of the MoCl₅ precursor material was greater than 1.2 times a theoretical vapor pressure of the MoCl₅ precursor material, the ampoule was pumped for 30 seconds, or pumped until the vapor pressure was 0.8 times the theoretical vapor pressure. The ampoule was held steady for 120 seconds and the method was repeated to determine whether the vapor pressure was greater than 1.2 times a theoretical vapor pressure of the MoCl₅ precursor material. If the vapor pressure was in the range of 1 to 1.2 times the theoretical vapor pressure, the ampoule was then cooled to ambient temperature and held at ambient temperature for 4 hours. If the pressure of the ampoule was greater than 0.5 Torr, the method was pumped until the pressure was less than 0.1 Torr. The method was repeated until the ampoule when cooled at ambient temperature, pressure was less than 0.5 Torr. At less than 0.5 Torr, the ampoule was purified and ready for use.

An on-site purification process for a system with an ampoule having WCl₅ precursor material was performed. The ampoule featured stainless steel trays. The systems modeled FIG. 2. The process included the installation of the ampoule having the WCl₅ precursor material. The ampoule was then pumped, and the pigtail valves were purged. The ampoule was then pumped until the pressure of the ampoule was less than 0.1 Torr. The pressure was monitored while pumping. If the pressure was above 0.5 Torr for less than 20 minutes, the ampoule was pumped again until the pressure was less than 0.1 Torr.

The ampoule was heated to the system operating temperature for 4 hours. If the vapor pressure of the WCl₅ precursor material was greater than 1.2 times a theoretical vapor pressure of the WCl₅ precursor material, the ampoule was pumped for 30 seconds, or pumped until the vapor pressure was 0.8 times the theoretical vapor pressure. The ampoule was held steady for 120 seconds and the method was repeated to determine whether the vapor pressure was greater than 1.2 times a theoretical vapor pressure of the WCl₅ precursor material. If the vapor pressure was in the range of 1 to 1.2 times the theoretical vapor pressure, the ampoule was then cooled to ambient temperature and held at ambient temperature for 4 hours. If the pressure of the ampoule was greater than 0.5 Torr, the method was pumped until the pressure was less than 0.1 Torr. The method was repeated until the ampoule when cooled at ambient temperature, pressure was less than 0.5 Torr. At less than 0.5 Torr, the ampoule was purified and ready for use.

Any one or more of the embodiments disclosed herein shall be understood to be combinable without departing from the scope or spirit of the disclosure.

### Aspects

Various Aspects are described below. It is to be understood that any one or more of the features recited in the following Aspect(s) can be combined with any one or more other Aspect(s).
Aspect 1. A system comprising:
   a cabinet,
      wherein the cabinet comprises:
         a first ampoule,
         wherein the first ampoule comprises:
         a first precursor material; and
         at least one first impurity;
         a manifold,
         wherein the manifold is connectable to a tool; and
         a first valve;
         wherein the first valve connects the first ampoule to the manifold;
         wherein the first valve has not been exposed to an external environment after the first valve has been exposed to the first precursor material.
Aspect 2. The system according to Aspect 1, wherein the first valve has not been exposed to ambient conditions after the first valve has been exposed to the first precursor material.
Aspect 3. The system according to any one of Aspects 1-2, wherein, when the first precursor material is vaporized to produce a first precursor vapor and when the first precursor vapor is delivered through the first valve and the manifold to the tool, an amount of the at least one first impurity present in the first precursor vapor is less than an amount of at least one impurity present in a control precursor vapor delivered from a control ampoule to a tool, wherein the control ampoule is connected to a control valve that has been exposed to an external environment after being exposed to the control precursor vapor.
Aspect 4. The system according to any one of Aspects 1-3, wherein the cabinet further comprises:
   a second ampoule,
      wherein the second ampoule comprises:
         a second precursor material; and
         at least one second impurity; and
      a second valve,
         wherein the second valve connects the second ampoule to the manifold.
Aspect 5. The system according to any one of Aspects 1-4, wherein the second valve has not been exposed to an external environment after the second valve has been exposed to the second precursor material.
Aspect 6. The system according to any one of Aspects 1-5, wherein, when the second precursor material is vaporized to produce a second precursor vapor and when the second precursor vapor is delivered through the second valve and the manifold to the tool, an amount of the at least one second impurity present in the second precursor vapor is less than an amount of at least one impurity present in a control precursor vapor delivered from a control ampoule to a tool, wherein the control ampoule is connected to a control valve that has been exposed to an external environment after being exposed to the control precursor vapor.
Aspect 7. A method comprising:
   obtaining a cabinet,
      wherein the cabinet comprises:
         a first ampoule,
         wherein the first ampoule comprises:
         a first precursor material; and
         at least one first impurity;
         a manifold,
         wherein the manifold is connectable to a tool;
         and
         a first valve;
         wherein the first valve connects the first ampoule to the manifold; and
      removing at least a portion of the at least one first impurity from the first ampoule,
   wherein, prior to the step of removing, the first valve has not been exposed to an external environment after the first valve has been exposed to the first precursor material.
Aspect 8. The method according to Aspect 7, wherein the first valve, after being connected to the first ampoule and after being exposed to the first precursor material, is not disconnected from the first ampoule so as to be exposed to the external environment.
Aspect 9. The method according to any one of Aspects 7-8, wherein the step of removing comprises:
   opening the first valve, so as to remove at least a portion of a vapor from the first ampoule,
      wherein the vapor comprises the at least one first impurity.
Aspect 10. The method according to any one of Aspects 7-9, wherein the step of removing comprises:
   evacuating the first ampoule under vacuum, so as to remove at least a portion of a vapor from the first ampoule;
      wherein the vapor comprises the at least one first impurity.
Aspect 11. The method according to any one of Aspects 7-10, wherein the step of removing comprises:
   heating the first ampoule to a temperature sufficient to obtain a vapor comprising at least a portion of the at least one first impurity; and
   removing the vapor from the first ampoule.
Aspect 12. The method according to any one of Aspects 7-11, wherein the step of removing comprises:
   heating the first ampoule to a first temperature sufficient to produce a vapor having a vapor pressure that is 1 to 1.2 times a theoretical vapor pressure of the first precursor material,
      wherein the vapor comprises the at least one first impurity; and removing the vapor from the first ampoule.
Aspect 13. The method according to any one of Aspects 7-12, wherein the step of removing further comprises:
   cooling the first ampoule to a second temperature,
      wherein the second temperature is less than the first temperature.
Aspect 14. The method of claim 7, wherein the step of removing is performed until a vapor pressure of a vapor removed from the first ampoule is within 20% of a theoretical vapor pressure of the first precursor material.
Aspect 15. A system comprising:
   a cabinet,
      wherein the cabinet comprises:
         a first ampoule,
         wherein the first ampoule comprises:
         a first precursor material; and
         at least one first impurity;
         a manifold,
         wherein the manifold is connected to a semiconductor tool;
         a first heater,
         wherein the first heater is configured to heat the first ampoule; and
         a first valve;
         wherein the first valve connects the first ampoule to the manifold;
         wherein the first valve has not been exposed to an external environment after the first valve has been exposed to the first precursor material.
Aspect 16. The system according to Aspect 15, wherein the first valve has not been exposed to ambient conditions after the first valve has been exposed to the first precursor material.
Aspect 17. The system according to any one of Aspects 15-16, wherein, when the first precursor material is vaporized to produce a first precursor vapor and when the first precursor vapor is delivered through the first valve and the manifold to the semiconductor tool, an amount of the at least one first impurity present in the first precursor vapor is less than an amount of at least one impurity present in a control precursor vapor delivered from a control ampoule to a semiconductor tool, wherein the control ampoule is connected to a control valve that has been exposed to an external environment after being exposed to the control precursor vapor.
Aspect 18. The system according to any one of Aspects 15-17, further comprising:
   a controller,
      wherein the controller is in communication with at least the first heater and the first valve;
      wherein the controller is configured to operate the first heater and the first valve so as to remove at least a portion of the at least one first impurity from the first ampoule.
Aspect 19. The system according to any one of Aspects 15-18, wherein the controller is configured to:
   heat the first ampoule to a temperature sufficient to obtain a vapor comprising at least a portion of the at least one first impurity; and
   remove at least a portion of the vapor from the first ampoule.
Aspect 20. The system according to any one of Aspects 15-19, wherein the semiconductor tool is a vapor deposition apparatus.
Aspect 21. The system according to any one of Aspects 1-6, further comprising a filter between the ampoule and the process tool to capture impurities traveling from the ampoule to the process tool.
Aspect 22. A method of providing a vaporized precursor to a semiconductor tool comprising:
   in a cabinet containing multiple ampoules which each contain precursor material:
      simultaneously delivering vaporized precursor from a first ampoule to the semiconductor tool; and
      purifying the precursor in a second ampoule,
   where the second ampoule is configured to provide vaporized precursor after the first ampoule to provide continuity of delivery of precursor to the semiconductor tool.
Aspect 23. The method according to Aspect 22, wherein purifying the precursor in the second ampoule comprises heating the second ampoule.
Aspect 24. The method according to any one of Aspects 22-23, wherein purifying the precursor in the second ampoule comprises removing volatilized contaminant vapor through a gas delivery line.
Aspect 25. A system for purifying precursor material comprising:
   an ampoule containing a precursor material to be delivered to a semiconductor tool;
   the semiconductor tool;
   a delivery line connecting the ampoule to the semiconductor tool, the delivery line comprising:
      a first and second valves in line with the delivery line and configured to isolate a portion of the delivery line; and
      a third valve between the first and second valves, the third valve connected to a vacuum such that vaporized material in the isolated portion of the delivery line can be removed from the delivery line.
Aspect 26. The system of Aspect 25, further comprising a second ampoule connected to the semiconductor tool, wherein the second ampoule provides vaporized precursor to the semiconductor tool while vaporized material in the isolated portion of the delivery line is removed from the delivery line.
Aspect 27. A method of using the system of one of Aspects 25-26, the method comprising:
   filling the portion of the delivery line between the first and second valves with vaporized material;
   closing the first valve to isolate the portion of the delivery line between the first and second valves;
   opening the third valve and removing the vaporized material from between the portion of the delivery line between the first and second valves;
   closing the third valve; and
   opening the first valve.
Aspect 28. The method of Aspect 27, wherein the steps of the method are repeated multiple times.
Aspect 29. The method of one of Aspects 27-28, further comprising measuring a vapor pressure in the ampoule.
Aspect 30. The method of one of Aspects 27-29, further comprising measuring a vapor pressure in the delivery line.
Aspect 31. The method of one of Aspects 29-30, further comprising comparing the measured pressure against a reference pressure, wherein the reference pressure may be fixed or calculated based on the precursor and the temperature.
Aspect 32. A system for delivering vaporized precursor to a semiconductor tool comprising:
   an ampoule containing precursor;
   a delivery line connecting the ampoule to the semiconductor tool and configured to deliver vaporized precursor from the ampoule to the semiconductor tool; and
   an inline filter in delivery line to improve the quality vaporized precursor delivered to the semiconductor tool.
Aspect 33. The system of Aspect 32, wherein the inline filter removes particulate.
Aspect 34. The system of any one of Aspects 32-33, wherein the inline filter removes a vaporized contaminant.
Aspect 35. The system of any one of Aspects 32-34, wherein the inline filter is located in a delivery cabinet.
Aspect 36. The system of any one of Aspects 32-35, wherein the inline filter is configured to be replaced without replacing or damaging the delivery line.

What is claimed is:

1. A system comprising:
a cabinet,
wherein the cabinet comprises:
a first ampoule,
wherein the first ampoule comprises:
a first precursor material; and
at least one first impurity;
a manifold,
wherein the manifold is connectable to a tool; and
a first valve;
wherein the first valve connects the first ampoule to the manifold;
wherein the first valve has not been exposed to an external environment after the first valve has been exposed to the first precursor material.

2. The system of claim 1, wherein the first valve has not been exposed to ambient conditions after the first valve has been exposed to the first precursor material.

3. The system of claim 1, wherein, when the first precursor material is vaporized to produce a first precursor vapor and when the first precursor vapor is delivered through the first valve and the manifold to the tool, an amount of the at least one first impurity present in the first precursor vapor is less than an amount of at least one impurity present in a control precursor vapor delivered from a control ampoule to a tool, wherein the control ampoule is connected to a control valve that has been exposed to an external environment after being exposed to the control precursor vapor.

4. The system of claim 1, wherein the cabinet further comprises:
a second ampoule,
wherein the second ampoule comprises:
a second precursor material; and
at least one second impurity; and
a second valve,
wherein the second valve connects the second ampoule to the manifold.

5. The system of claim 4, wherein the second valve has not been exposed to an external environment after the second valve has been exposed to the second precursor material.

6. The system of claim 1, further comprising a filter located on a line connecting the first ampoule and a semiconductor tool.

7. A method comprising:
obtaining a cabinet,
wherein the cabinet comprises:
a first ampoule,
wherein the first ampoule comprises:
a first precursor material; and
at least one first impurity;
a manifold,
wherein the manifold is connectable to a tool; and
a first valve;
wherein the first valve connects the first ampoule to the manifold; and
removing at least a portion of the at least one first impurity from the first ampoule,
wherein, prior to the step of removing, the first valve has not been exposed to an external environment after the first valve has been exposed to the first precursor material.

8. The method of claim 7, wherein the first valve, after being connected to the first ampoule and after being exposed to the first precursor material, is not disconnected from the first ampoule so as to be exposed to the external environment.

9. The method of claim 7, wherein the step of removing comprises:
opening the first valve, so as to remove at least a portion of a vapor from the first ampoule,
wherein the vapor comprises the at least one first impurity.

10. The method of claim 7, wherein the step of removing comprises:
evacuating the first ampoule under vacuum, so as to remove at least a portion of a vapor from the first ampoule;
wherein the vapor comprises the at least one first impurity.

11. The method of claim 7, wherein the step of removing comprises:
heating the first ampoule to a temperature sufficient to obtain a vapor comprising at least a portion of the at least one first impurity; and
removing the vapor from the first ampoule.

12. The method of claim 7, wherein the step of removing comprises:
heating the first ampoule to a first temperature sufficient to produce a vapor having a vapor pressure that is 1 to 1.2 times a theoretical vapor pressure of the first precursor material,
wherein the vapor comprises the at least one first impurity; and
removing the vapor from the first ampoule.

13. The method of claim 12, wherein the step of removing further comprises:
cooling the first ampoule to a second temperature,
wherein the second temperature is less than the first temperature.

14. The method of claim 7, wherein the step of removing is performed until a vapor pressure of a vapor removed from the first ampoule is within 20% of a theoretical vapor pressure of the first precursor material.

15. A system comprising:
a cabinet,
wherein the cabinet comprises:
a first ampoule,
wherein the first ampoule comprises:
a first precursor material; and
at least one first impurity;
a manifold,
wherein the manifold is connected to a semiconductor tool;
a first heater,
wherein the first heater is configured to heat the first ampoule; and
a first valve;
wherein the first valve connects the first ampoule to the manifold;
wherein the first valve has not been exposed to an external environment after the first valve has been exposed to the first precursor material.

16. The system of claim 15, wherein the first valve has not been exposed to ambient conditions after the first valve has been exposed to the first precursor material.

17. The system of claim 15, wherein, when the first precursor material is vaporized to produce a first precursor vapor and when the first precursor vapor is delivered through the first valve and the manifold to the semiconductor tool, an amount of the at least one first impurity present in the first precursor vapor is less than an amount of at least one impurity present in a control precursor vapor delivered from a control ampoule to a semiconductor tool, wherein the control ampoule is connected to a control valve that has been exposed to an external environment after being exposed to the control precursor vapor.

18. The system of claim 15, further comprising:
a controller,
wherein the controller is in communication with at least the first heater and the first valve;
wherein the controller is configured to operate the first heater and the first valve so as to remove at least a portion of the at least one first impurity from the first ampoule.

19. The system of claim 18, wherein the controller is configured to:
heat the first ampoule to a temperature sufficient to obtain a vapor comprising at least a portion of the at least one first impurity; and
remove at least a portion of the vapor from the first ampoule.

20. The system of claim 15, further comprising a filter located on a line connecting the first ampoule and the semiconductor tool.
